(19) United States
(12) Patent Application Publication
(10) Pub. No.: US 2023/0020696 A1
(43) Pub. Date: Jan. 19, 2023

(54) MEMORY DEVICE AND FORMATION METHOD THEREOF

(71) Applicant: TAIWAN SEMICONDUCTOR MANUFACTURING COMPANY, LTD., Hsinchu (TW)

(72) Inventors: Kuo-Pin CHANG, Hsinchu County (TW); Chien-Hung LIU, Hsinchu County (TW); Chih-Wei HUNG, Hsinchu City (TW)

(73) Assignee: TAIWAN SEMICONDUCTOR MANUFACTURING COMPANY, LTD., Hsinchu (TW)

(21) Appl. No.: 17/377,772

(22) Filed: Jul. 16, 2021

(51) Int. Cl. H01L 27/112

(52) U.S. Cl. CPC H01L 27/11206

(57) ABSTRACT

An anti-fuse memory cell includes a substrate, a gate dielectric layer over the substrate, a word line gate over the gate dielectric layer, a first implant region on a first side of the word line gate, a bit line contact plug over the first implant region, a second implant region on a second side of the word line gate opposite the first side of the word line gate, an oxidized region on the second implant region and having a convex upper surface and a source line gate over the convex upper surface of the oxidized region.

### BACKGROUND

Many integrated circuits (ICs) are made up of millions of interconnected devices, such as transistors, resistors, capacitors, and diodes, on a single chip of semiconductor substrate. It is generally desirable that ICs operate as fast as possible, and consume as little power as possible. Semiconductor ICs often include one or more types of memory, such as complementary metal-oxide-semiconductor memory, anti-fuse memory, and Efuse memory.

### BRIEF DESCRIPTION OF THE DRAWINGS

Aspects of the present disclosure are best understood from the following detailed description when read with the accompanying Figures. It is noted that, in accordance with the standard practice in the industry, various features are not drawn to scale. In fact, the dimensions of the various features may be arbitrarily increased or reduced for clarity of discussion.

FIGS. 1 through 13 illustrate the cross-sectional views of intermediate stages in the formation of memory cell in accordance with some embodiments of the present disclosure.

FIG. 14 is an equivalent circuit diagram of the memory cell in FIG. 13.

FIG. 15 shows a layout of an array architecture of the memory cells according to some embodiments of the present disclosure.

FIGS. 16A-16D are enlarged views of partial regions in FIG. 13 showing current flow in a programming process of the memory cell in accordance with some embodiments.

FIG. 17 is an equivalent circuit diagram of the layout the memory cells and the conductive lines in accordance with some embodiments.

FIG. 18 is an operating table of FIG. 17.

FIG. 19 is a voltage biased conditions assigned to word lines, bit line, source lines of the selected block and the remaining multiple unselected blocks within the memory array in a program operation of the present disclosure.

FIG. 20 is a voltage biased conditions assigned to word lines, bit line, source lines of the selected block and the remaining multiple unselected blocks within the memory array in a read operation of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the Figures. The spatially relative terms are intended to encompass different orientations of the device in use or operation in addition to the orientation depicted in the Figures. The apparatus may be otherwise oriented (rotated 90 degrees or at other orientations) and the spatially relative descriptors used herein may likewise be interpreted accordingly. In certain embodiments, the term “about” used in this context means greater or less than the stated value or the stated range of values by a percentage such as 5%, 10%, 15%, etc. of the stated values.

Memory arrays use an anti-fuse layer to store multiple bit digital data. The memory arrays include three-dimensional memory cell arrays. Each memory cell includes a diode and an anti-fuse layer. The anti-fuse layer acts initially as an insulator, blocking forward current through the memory cell. The memory cell can be programmed by sending a write voltage/current through the memory cell to disrupt the anti-fuse layer, thereby lowering the resistance of the memory cell. The contents of the memory cell can be read as logic 1 if the memory cell resistance is in a lower range, indicating that the anti-fuse layer has been disrupted, and as logic 0 if the resistance is at a higher initial level.

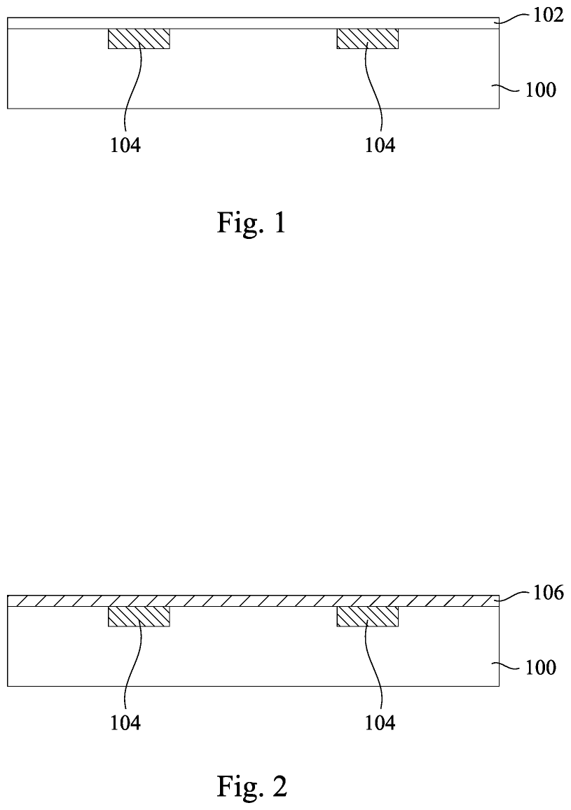

FIGS. 1 through 13 illustrate the cross-sectional views of intermediate stages in the formation of an anti-fuse memory cell in accordance with some embodiments of the present disclosure.

Reference is made to FIG. 1. A sacrificial (SAC) oxide layer 102 is formed over a substrate 100. After forming the sacrificial oxide layer 102, a well/threshold voltage (Vt) implant operation is optionally performed to introduce dopant impurities into the substrate 100 in the transistor region within which the transistor channel will be formed to form threshold implant regions 104. The sacrificial oxide layer 102 may be formed by suitable processes such as thermal oxidation, wet oxidation or the like. The sacrificial oxide layer 102 may serve as a protection layer during the threshold voltage implant operation. The dopant impurities can be P-type dopant impurities such as boron or other suitable species, according to some exemplary embodiments, and can be N-type dopant impurities such as phosphorous, antimony, or arsenic, according to other exemplary embodiments. As referred to herein, the Vₜ implant operation introduces dopant impurities of a first dopant impurity type (either N-type or P-type) and is a lower power implant. Various suitable implantation powers and energies can be used. The Vₜ implant introduces impurities into the channel to adjust the Vₜ (threshold voltage) applied to the transistor to open the channel to current flow and may also be referred to as a Vₜ adjust implant. The substrate 100 may be a semiconductor substrate, which may be a silicon substrate, a silicon germanium substrate, or a substrate formed of other semiconductor materials. The substrate 100 may be doped with a p-type or an n-type impurity.

After the threshold voltage implant operation is performed, the sacrificial oxide layer 102 is removed and then a gate dielectric layer 106 is formed over the substrate 100 thereafter. The resulting structure is illustrated in FIG. 2. The gate dielectric layer 106 is, for example, an oxide layer, such as silicon dioxide.

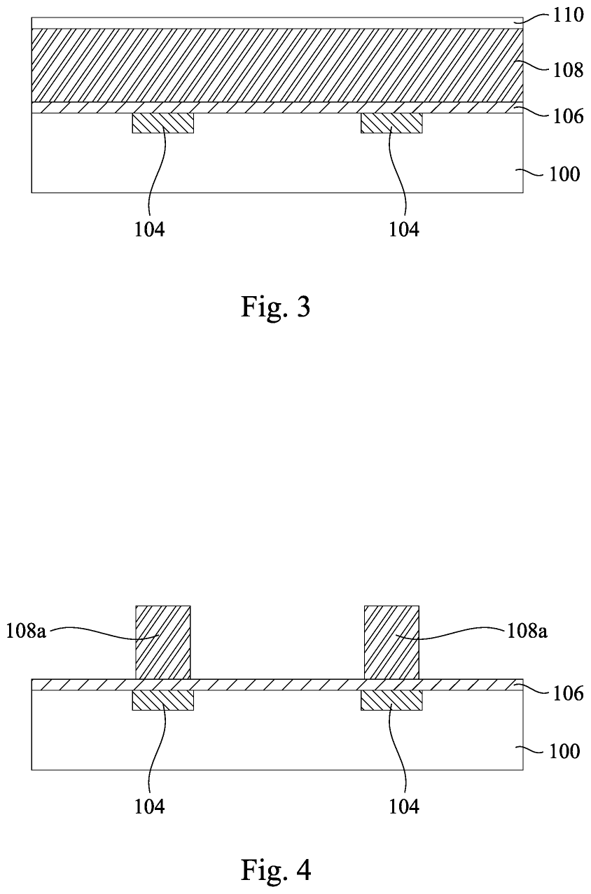

A poly gate material 108 is formed on the gate dielectric layer 106 as illustrated in FIG. 3. The poly gate material includes silicon, such as polycrystalline silicon (polysilicon). In the present embodiment, the poly gate material 108 may be non-doped. The poly gate material 108 alternatively or additionally may include amorphous silicon.

In various embodiments, a hard mask layer 110, such as silicon nitride (SiN) or silicon oxide (SiO₂), is further formed on the poly gate material 108 for gate patterning. The non-doped amorphous silicon or polysilicon layer 108 can be formed using chemical vapor deposition (CVD) with precursor silane (SiH₄) or other silicon based precursor. The deposition of the non-doped amorphous silicon layer can be performed at a raised temperature. The hard mask layer (SiN or SiO₂) 110 can be formed by CVD or other suitable technique.

The poly gate material 108 is patterned to form one or more poly gates 108a on the overlay region, for example, threshold implant regions 104, as illustrated in FIG. 4. The poly gates 108a will serve as word lines of the anti-fuse memory cell, and thus this step can also be referred to as a word line patterning process. The patterning of the poly gate material 108 can be achieved by a lithography process and/or an etch process. For example, a patterned photoresist layer is formed on the hard mask layer 110 defining various gate regions, using a photolithography process including photoresist coating, soft baking, exposing, post-exposure baking (PEB), developing, and hard baking. Then, the hard mask layer 110 is etched through the openings of the patterned photoresist layer, forming a patterned hard mask. The poly gate material 108 is further etched using the patterned hard mask, forming the various poly gates 108a. The patterned photoresist layer is removed thereafter using a suitable process, such as wet stripping or plasma ashing. Alternatively, if the hard mask layer 110 is not present, then the patterned photoresist layer is directly utilized as an etch mask to etch the poly gate material 108.

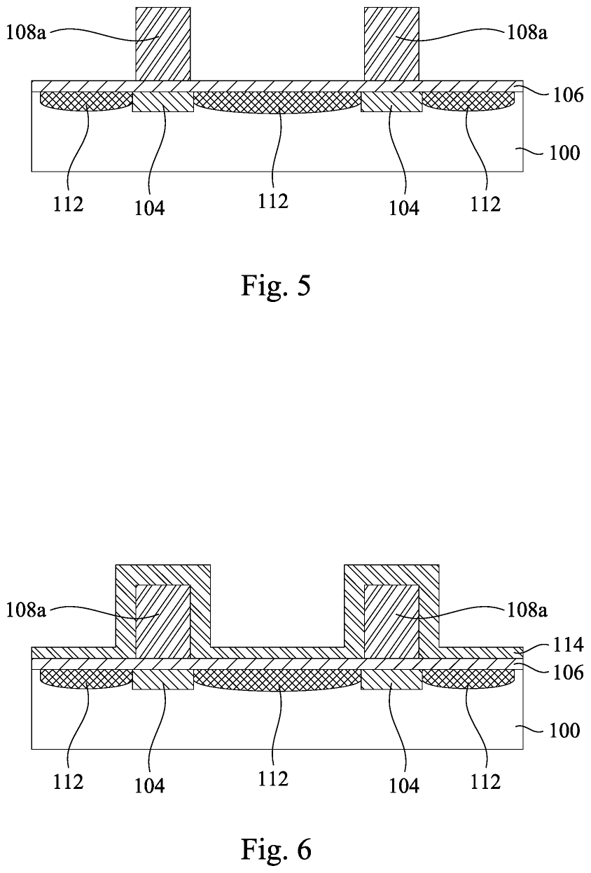

Referring to FIG. 5, a light doped drain (LDD) implant operation is performed to introduce dopant impurities into regions of the substrate 100, which are not covered by the poly gates 108a, to form light doped drain (LDD) regions 112. The LDD regions 112 are laterally between the threshold implant regions 104. In this embodiment, the LDD regions 112 are laterally in contact with the threshold implant regions 104. In this embodiment, the LDD regions 112 are formed after the formation of the poly gate 108a. In one example, an n-type dopant, such as phosphorous or arsenic, is introduced to the substrate 100 to form n-type LDD regions. In another embodiment, a p-type doping species, such as boron (B), may be alternatively used to form p-type LDD regions 112. As is illustrated in FIG. 5, the LDD regions 112 are aligned with the outer boundaries of the poly gates 108a. Since no photolithography process is required to define the area or the boundaries of the LDD regions 112, it may be said that the LDD regions 112 are formed in a “self-aligning” manner.

Reference is made to FIG. 6. A spacer layer 114 is blanked formed over the poly gates 108a and the gate dielectric layer 106. In other words, the spacer layer 114 is a substantially conformal layer and is conformally formed over the poly gates 108a and the gate dielectric layer 106. For example, the spacer layer 114 extends from the gate dielectric layer 106 directly above the LDD region 112 and then extends to a sidewall of the poly gate 108a and cover a top of the poly gate 108a. A thickness of a portion of the spacer layer 114 directly above the LDD region 112 is the same as a thickness of a portion of the spacer layer 114 over the sidewall of the poly gate 108a and a thickness of a portion of the spacer layer 114 over the top of the poly gate 108a, respectively. The spacer layer 114 may include, for example, silicon oxide or other suitable dielectric materials.

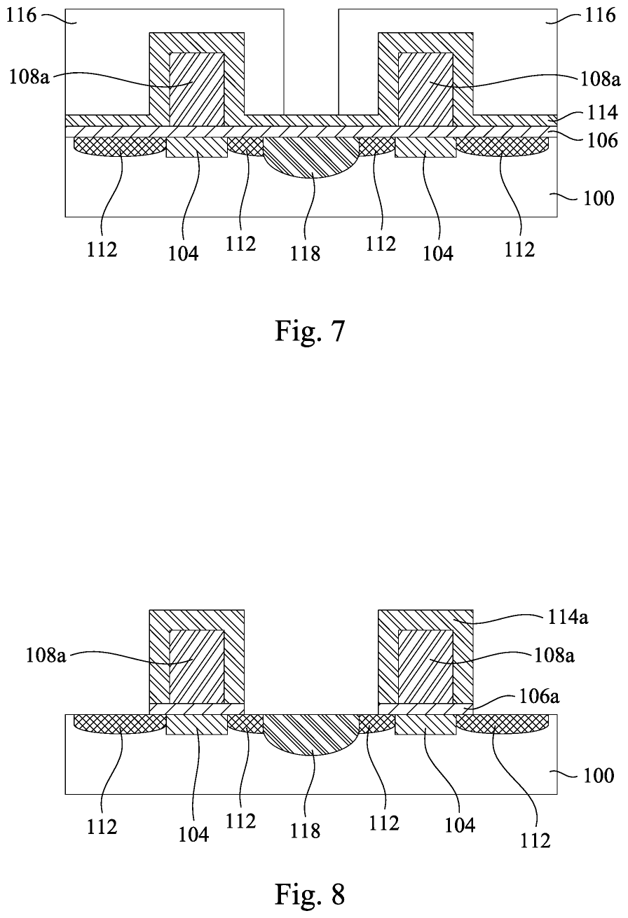

Reference is made to FIG. 7. A patterned photoresist 116 is formed over the spacer layer 114. In particular, the patterned photoresist 116 overlays the spacer layer on sidewalls and tops of each of the poly gates 108a and has an opening exposing a part of the spacer layer 114 between the adjacent poly gates 108a. The formation of the patterned photoresist 116 may involve one or more spin coating, exposing, developing, baking, and rinsing processes (not necessarily performed in that order). A source line implant operation is performed to introduce dopant impurities into a region under the exposed part of the spacer layer 114 to form an implant region 118. The dopant impurity in the implant region 118 is of a conductivity type opposite a conductivity type of the LDD regions 112, and thus the implant region 118 serve to provide electrical isolation between bit to bit, which will be described later. The implant region 118 is laterally between the poly gates 108a. By way of example, when the LDD regions 112 are doped with n-type dopants, the source line implant operation may use p-type dopants such as As or Xe atoms, or combinations thereof as dopants. The patterned photoresist 116 is removed afterwards by ashing, stripping or other suitable processes after the source line implant operation. The implant region 118 has a first type of dopants different from a second type of dopants of the LDD regions 112. For example, the first type of dopants of the implant region 118 is p-type and the second type of dopants of the LDD regions 112 is n-type. In some embodiments, the vertical depth of the implant region 118 is greater than a vertical depth of the LDD region extending from the top of the substrate 100 down in to the substrate 100. In other embodiments, the vertical depth of the implant region 118 is greater than a vertical depth of the threshold implant regions 104 extending from the top of the substrate 100 down into the substrate 100.

The spacer layer 114 is patterned by an etch process, forming gate spacers 114a wrapping around three sides of the poly gates 108a, as shown in FIG. 8. For example, the gate spacers 114a wrap around the opposite sidewalls and the tops of the poly gates 108a. That is, a horizontal portion of the spacer layer extending along the gate dielectric layer 106 is removed. The gate dielectric layer 106 is patterned by an etch process to form gate dielectric layers 106a as well. The etch process may be suitable etching techniques, such as wet etching, dry etching or combinations thereof. In some embodiments, the spacer layer 114 and the gate dielectric layer 106 are patterned using a single etching process. Alternatively, the spacer layer 114 and the gate dielectric layer 106 are pattered using different etching processes. The gate dielectric layer 106a has a width substantially the same as a width of a top surface of the gate spacer 114a. The spacer layer 114 over the LDD regions 112 is partially removed such that the LDD regions 112 are partially exposed. The spacer layer 114 over the implant region 118 is totally removed such that the implant region 118 is exposed. The LDD regions 112 on opposing sides and in contact with the implant region 118 which are not covered by the gate dielectric layer 106a are exposed as well. The gate spacers 114a surround the poly gates 108a. For example, the gate spacers 114a extend from a top of the gate dielectric layer 106a and the sidewall of the poly gate 104a to cover the top of the poly gate 108a.

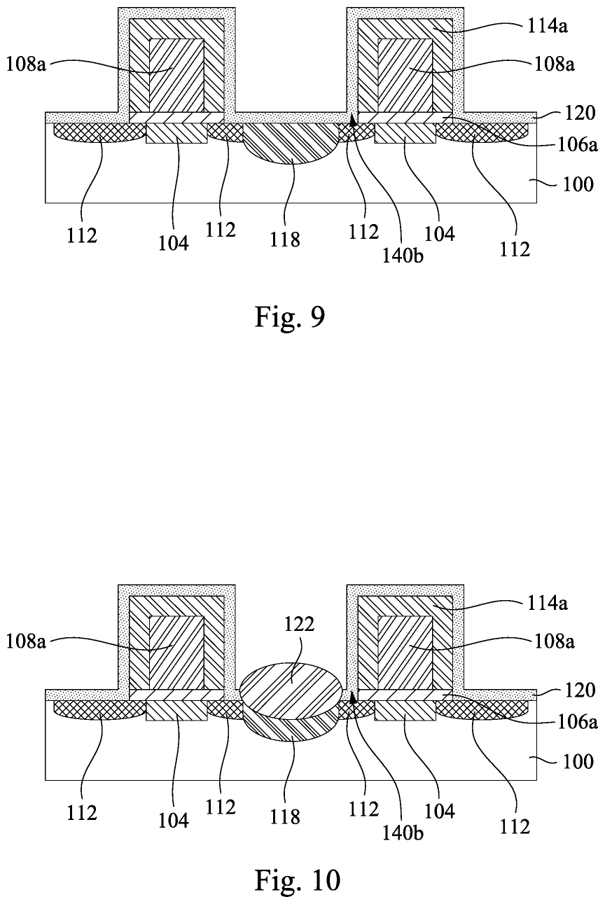

Reference is made to FIG. 9. An oxide layer 120 is blanked formed over the substrate and the gate spacers. In other words, the oxide layer 120 is a substantially conformal layer and is conformally formed over the LDD regions 112, the gate dielectric layer 106a, the gate spacers 114a and the implant region 118. For example, the spacer layer 114 extends from over the LDD region 112, along a sidewall of the gate dielectric layer 106a, along the sidewall of the gate spacer 114a, covers a top of the gate spacer 114a and extends along an opposing sidewall of the gate spacer 114a, an opposing sidewall of the gate dielectric layer 106a, over the top of the LDD region 112 adjacent to the implant region 118 and over the top of the implant region 118. The oxide layer 120 serves as a breakdown layer. That is, the oxide layer 120 is prone to current leakage and electrical breakdown, so as to enable operations of anti-fuse memory cell (e.g., writing operation). In some embodiments, the oxide layer 120 has a material same as a material of the spacer layer 114. For example, the oxide layer 120 and the spacer layer 114 include silicon oxide. In some embodiments where the oxide layer 120 and the spacer layer 114 have the same material, the oxide layer 120 and the spacer layer 114 may have no distinguishable interface therebetween. Since the oxide layer 120 is a conformal layer, the oxide layer 120 has a uniform thickness. That is, a thickness of the oxide layer 120 over the implant region 118 is substantially the same as a thickness of the oxide layer 120 over the LDD regions 112, the gate spacers 114a, and the gate dielectric layers 106a.

Reference is made to FIG. 10. A portion of the oxide layer 120 over the implant region 118 is removed to expose the implant region 118, and then an oxidation process is performed on the implant region 118 to form a source line oxide 122 that is thicker than the previously deposited oxide layer 120. As shown in FIG. 10, the poly gates 108a are on opposite sides of the source line oxide 122, respectively. The source line oxide 122 raises above a top surface of the substrate 100. The oxidation process may include, for example, thermal oxidation, wet oxidation, chemical oxidation, the like, or combinations thereof. The source line oxide 122 has a topmost position higher than a top surface of the gate dielectric layer 106a. Although an interface is illustrated between the source line oxide 122 and the oxide layer 120 for description, the source line oxide 122 and the oxide layer 120 may have no distinguishable interface in some embodiments. The source line oxide 122 over the implant region 118 has a profile different from a profile of the oxide layer 120 over the implant region 118 before the oxidation process. For example, the source line oxide 122 has an enlarged profile such that the source line oxide 122 can provide isolation between adjacent memory cells and thus suppress the leakage therebetween, which will described later. The oxide layer 120 over regions of the substrate 100 other than the implant region 118 has a profile remain unchanged. After growing the source line oxide 122, the implant region 118 has a concave upper surface.

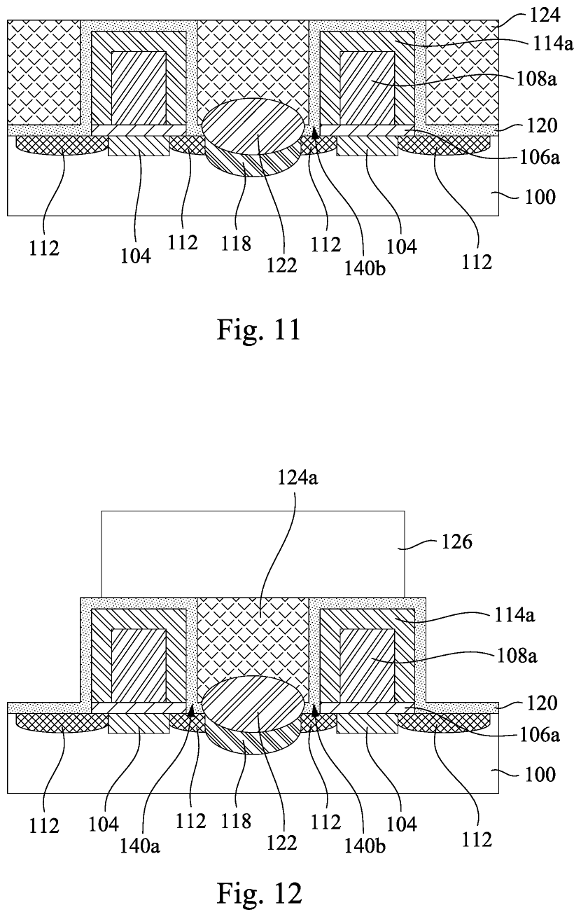

Due to growing from the implant region 118, the source line oxide 122 has an oval shape when viewed from cross section. Such oval shape is beneficial for providing opposing point discharge structures for a subsequently formed overlying layer (e.g., poly gate material 124 in FIG. 11). In other words, the source line oxide 122 has a curved bottom surface and a curved top surface connected to the curved top surface. For example, the source line oxide 122 has a convex upper surface and a convex lower surface. That is, the source line oxide 122 has a vertical thickness decreasing in a direction extending from a center of the source line oxide 122 to opposite edges of the source line oxide 122. For example, the source line oxide 122 has a convex bottom surface extending towards the implant region 118 and a convex top surface protruding in a direction away from the implant region 118. For example, the bottommost surface of the source line oxide 122 is lower than a bottommost surface of the oxide layer 120 over the LDD regions 112.

The source line oxide 122 has a thickness different from a thickness of the oxide layer 120 over the LDD regions 112. For example, the source line oxide 122 has a thickness greater than thicknesses of the oxide layer 120 over the LDD regions 112 and over the gate spacers 114a, respectively. In some embodiments, a maximum thickness of the source line oxide 122 is in a range from about 200 angstrom to about 1000 angstrom. In some embodiments, the thickness of the oxide layer 120 is in a range from about 15 angstrom to about 90 angstrom.

Reference is made to FIG. 11. A poly gate material 124 is deposited over the oxide layer 120 and the source line oxide 122 and planarized by a suitable planarization, for example, a chemical mechanical planarization (CMP) to expose top surfaces of the oxide layer 120 overlying the poly gates 108a and level the top surface of the oxide layer overlying the poly gates 108a and the top surface of the poly gate material 124. The poly gate material 124 includes silicon, such as polycrystalline silicon (polysilicon). In the present embodiment, the poly gate material 124 may be non-doped. The poly gate material 108 alternatively or additionally may include amorphous silicon.

Because the source line oxide 122 has a convex top surface, the poly gate material 124 overlying the source line oxide 122 has a concave bottom surface protruding away from the source line oxide 122. As a result, the logic poly gate material 124 has opposing bottom tip portions which can provide point discharge structure. The source line oxide 122 has a center thickness different from an edge thickness of the source line oxide 122. The point discharge structure can greatly enhance an oxide breakdown due to providing the high electric filed. In particular, each of the bottom tip portions of the logic poly gate material 124 has a width decreasing in a direction toward the LDD region 112. The poly gate material 124 further has opposing horizontal bottom surfaces connected to and on opposite sides of the concave bottom surface of the poly gate material 124. The opposing horizontal bottom surfaces of the poly gate material 124 are in contact with the oxide layer over the LDD regions 112 on the opposing sides of the implant region 118. For example, the opposing horizontal bottom surfaces of the poly gate material 124 are lower than the concave surface of the poly gate material 124. In other words, the opposing horizontal bottom surfaces of the poly gate material 124 is closer to the substrate 100 than the concave surface of the poly gate material 124 is.

A photoresist (not shown) is formed over the poly gate material 124 and the oxide layer 120 and then patterned to form a patterned photoresist 126, as shown in FIG. 12. The patterned photoresist 126 is configured to define the logic poly gate 124a over the source line oxide 122. An etching process is performed to remove the exposed portion of the poly gate material 124 over the oxide layer 120 to form the logic poly gate 124a which is over the source line oxide 122. The patterned photoresist 126 is removed afterwards by ashing, stripping or other suitable processes. The logic poly gate 124a has a top surface higher than top surfaces of the poly gates 108a.

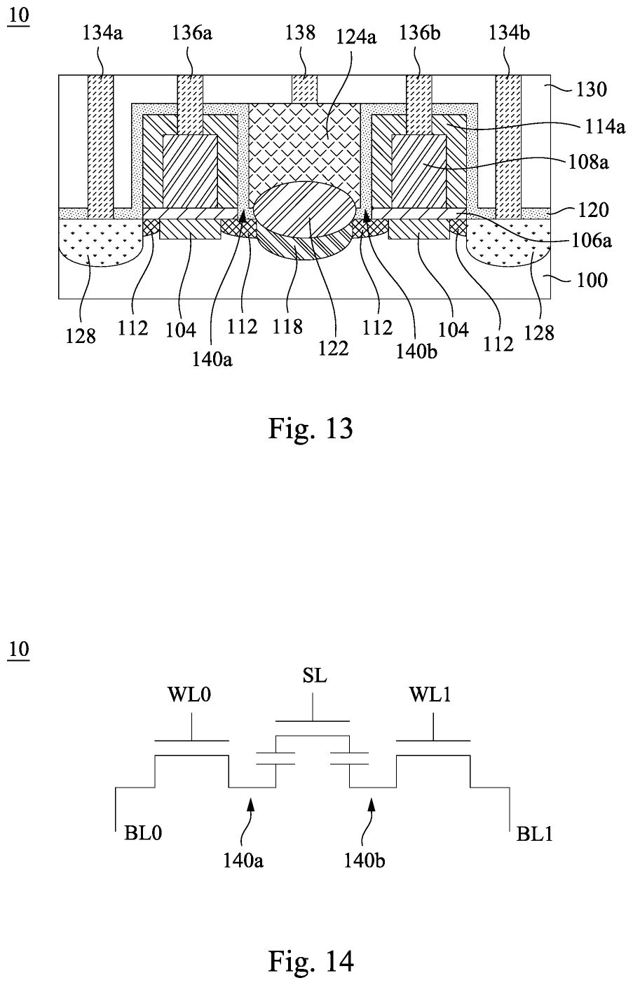

Reference is made to FIG. 13. A junction implant operation is performed to introduce dopant impurities into the substrate 100 to form junction implant regions 128. The junction implant regions 128 are on opposite sides of the logic poly gate 124a. The junction implant regions 128 are on sides of the poly gates 108a away from the logic poly gate 124a, respectively. The poly gates 108a are laterally between the junction implant regions 128. Thereafter, an inter-layer dielectric (ILD) 130 is formed and etched to form contact openings. In a subsequent step, a first bit line contact plug 134a, a second bit line contact plug 134b, a first word line contact plug 136a, a second word line contact plug 136b and source line contact plug 138 are formed in the contact openings. Thus, the memory cell 10 is formed. The LDD regions 112 directly below the gate dielectric layer 106a and the gate spacer 114a are not implanted during forming the junction implant regions 128.

The junction implant regions 128 are of the same conductivity type as the LDD regions 112, and thus the junction implant regions 128 are of a conductivity type opposite a conductive type of the implant region 118. In one example if the implant region 118 is of p-type, then an n-type dopant, such as phosphorous or arsenic, is introduced to the substrate 100 to form the n-type junction implant regions 128. In another embodiment, a p-type doping species, such as boron (B), may be alternatively used to form p-type junction implant regions 128.

The first bit line contact plug 134a and the second bit line contact plug 134b extend penetrating the ILD layer 130 and the oxide layer 120 to be in electrically contact with the junction implant regions 128. The first word line contact plug 136a and the second word line contact plug 136b extend penetrating the ILD layer 130, the oxide layer 120 over the logic poly gate 124a and the gate spacer 114a to be in electrically contact with the logic poly gate 124a. The source line contact plug 138 extends penetrating the ILD layer 130 to be in electrically contact with the logic poly gate 124a. The bottoms of the junction implant regions 128 are lower than the bottoms of the LDD regions 112.

FIG. 14 is an equivalent circuit diagram of the memory cell 10 in FIG. 13. Reference is made to FIGS. 13 and 14. The oxide layer 120 between the source line contact plug 138 and the first word line contact plug 136a form a first anti-fuse 140a, which may be programmed through the first word line contact plug 136a and the source line contact plug 138. The oxide layer 120 between the source line contact plug 138 and the second word line contact plug 136b form a second anti-fuse 140b, which may be programmed through the second word line contact plug 136b and the source line contact plug 138. Two word lines share the same source line but controls different anti fuses. For example, a first word line WL0 and a second word line WL1 share a source line SL0. The first word line WL0 controls the first anti-fuse 140a and the second word line WL1 controls the second anti-fuse 140b.

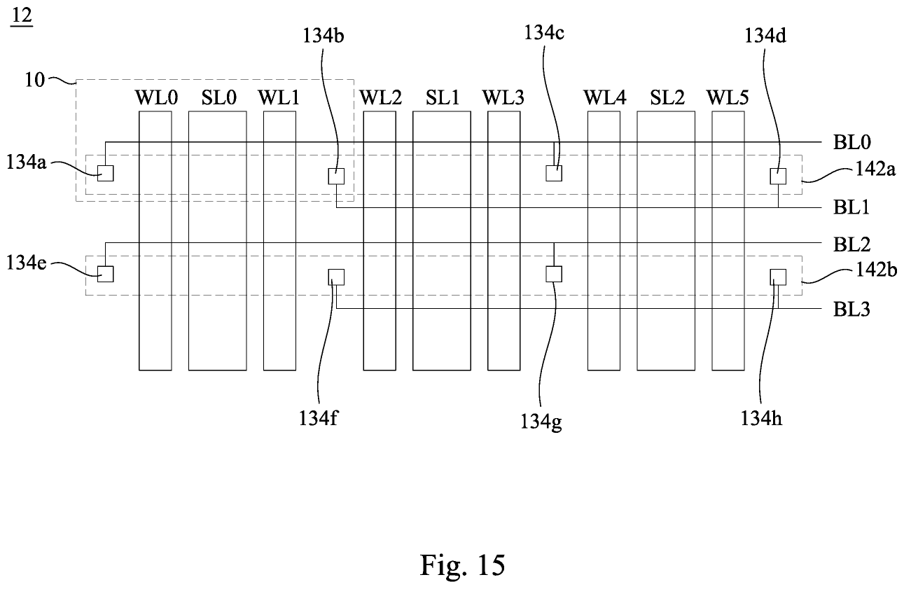

FIG. 15 shows a layout of an array architecture 12 of the memory cells 10 according to some embodiments of the present disclosure. Reference is made to FIGS. 13 and 15. The array architecture 12 includes respective oxide definition (OD) regions 142a and 142b. The OD regions 142a and 142b can be spaced apart from each other by in isolation structure (not labeled). The isolation structure can include a shallow trench isolation (STI) structure and/or a local oxidation of silicon (LOCOS) structure.

The OD region 142a can provide desired electrical contacts with a first bit line contact plug 134a, a second bit line contact plug 134b, a third bit line contact plug 134c and a fourth bit line contact plug 134d that are formed on the OD region 142a.

A first bit line BL0 is placed on the first bit line contact plug 134a. A second bit line BL1 is placed on the second bit line contact plug 134b. The first bit line BL0 is placed on the third bit line contact plug 134c. The second bit line BL1 is placed on the fourth bit line contact plug 134d.

The OD region 142b can provide desired electrical contacts with a fifth bit line contact plug 134e, sixth bit line contact plug 134f, a seventh bit line contact plug 134g and eighth bit line contact plug 134h that are formed on the OD region 142b. A third bit line BL2 is placed on the fifth bit line contact plug 134e. A fourth bit line BL3 is placed on the sixth bit line contact plug 134f. The third bit line BL2 is placed on the seventh bit line contact plug 134g. The fourth bit line BL3 is placed on the eighth bit line contact plug 134h.

When viewed from top, the word lines WL0, WL1, WL2, WL3, WL4 and WL5 extend along a direction same as that of the source lines SL0, SL1 and SL2. The word lines WL0-WL5 extend in the direction different from the bit lines BL0-BL3. The source lines SL0-SL2 extend in the direction different from the bit lines BL0-BL3 as well. For example, the bit lines BL0, BL1, BL2 and BL3 run parallel to the width of the word lines WL0, WL1, WL2, WL3, WL4 and WL5 and the source lines SL0, SL1 and SL2, while the word lines WL0-WL5 and the source lines SL0-SL2 run parallel with each other. The first source word line SL0 is placed between the first word line WL0 and the second word line WL1. The second source line SL1 is placed between the third word line WL2 and the fourth word line WL3. The third source line SL2 is placed between the fifth word line WL4 and the six word line WL5.

The first bit line contact plug 134a connects the gate transistor drain node with the first bit line BL0. The first word line WL0 is placed on the first word line contact plug 136a. The second word line WL1 is placed on the second word line contact plug 136b. The source line SL0 is placed on the source line contact plug 138. The anti fuses in the same bit line are isolated by the source line oxide 122. For example, the first anti-fuse 140a in the first bit line BL0 are isolated by the source line oxide 122. The second anti-fuse 140b in the second bit line BL1 are isolated by the source line oxide 122. As a result, the memory cell 10 has a small cell area and thus can be used for all technology nodes. The memory cell 10 is compatible to a metal-gate process as well.

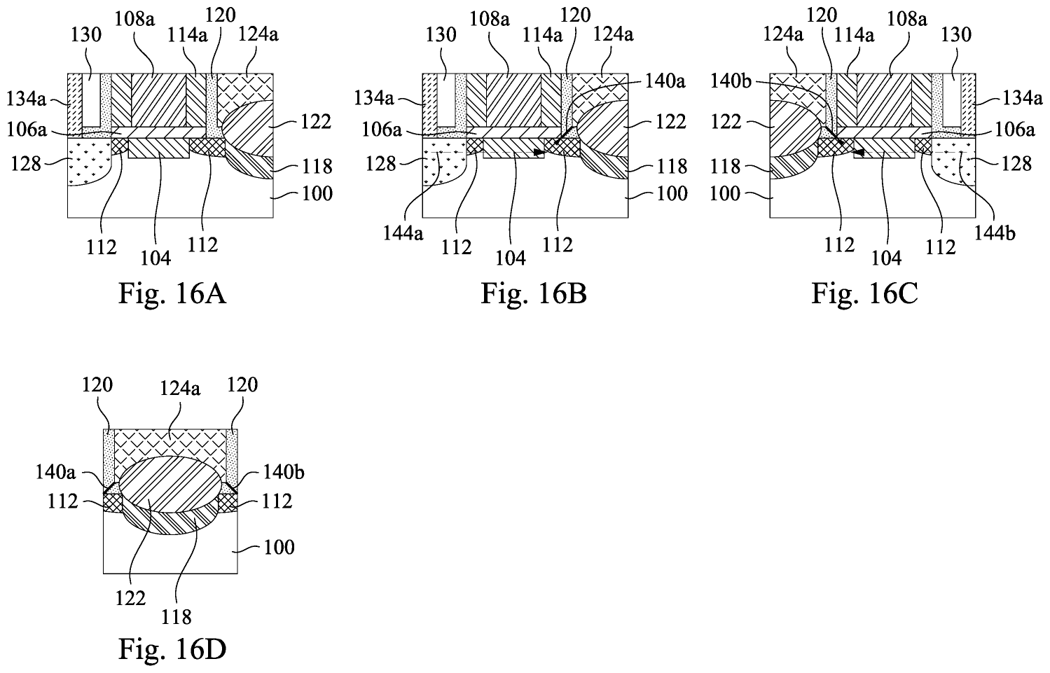

FIGS. 16A-16D are enlarged views of partial regions in FIG. 13 showing current flow in a programming process of the memory cell 10 in accordance with some embodiments. Referring first to FIG. 16A, when the memory cell 10 is not programmed, current may not flow from the junction implant region 128 through the threshold implant region 104 to reach the opposing tip portions of the logic poly gate 124a to form the first anti-fuse 140a (see FIG. 16B) or the second anti-fuse 140b (see FIG. 16C), respectively. To program the first bit in the bit line BL0 of the memory cell 10, a current 144a (illustrated as arrows) flows from the junction implant region 128 through the threshold implant region 104. Because the oxide layer 120 near the bottom tip portion of the logic poly gate 124a tends to be breakdown due to the bottom tip portion of the logic poly gate 124a providing point discharge structure, the current 144a may flow from the junction implant region 128 through the threshold implant region 104 to reach the tip portion of the logic poly gate 124a. Therefore, the first anti-fuse 140a is formed, as shown in FIG. 16B. To program the second bit in the bit line BL1 of the memory cell 10, a current 144b (illustrated as arrows) flows from the junction implant region 128 through the threshold implant region 104. Because the oxide layer 120 near the bottom tip portion of the logic poly gate 124a tends to be breakdown due to the bottom tip portion of the logic poly gate 124a providing point discharge structure, the current 144b may flow from the junction implant region 128 through the threshold implant region 104 to reach the bottom tip portion of the logic poly gate 124a. Therefore, the second anti-fuse 140b is formed, as shown in FIG. 16C. FIG. 16D is an enlarged view showing the memory cell 10 after the programming process. Referring to FIG. 16D, the first anti-fuse 140a and the second anti-fuse 140b are spaced apart by the source line oxide 122. As mentioned above, due to the oval profile of the source line oxide 122, the center of the source line oxide 122 is thick enough such that the source line oxide 122 can provide good electrical isolation between the first bit in the bit line BL0 and the second bit in the second bit line BL1. In particular, the implant region 118 can also provide good electrical isolation between the first bit in the first bit line BL0 and the second bit in the second bit line BL2.

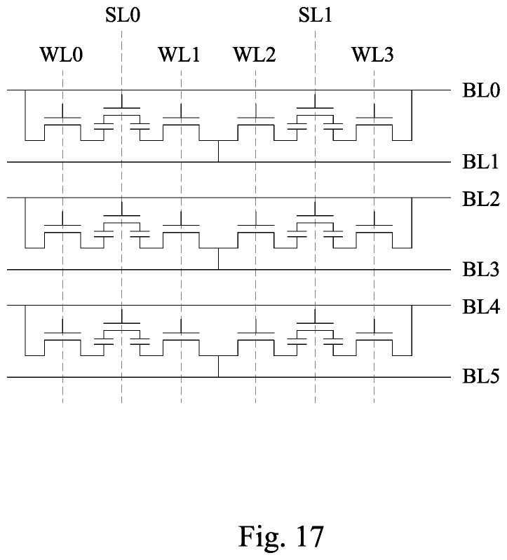

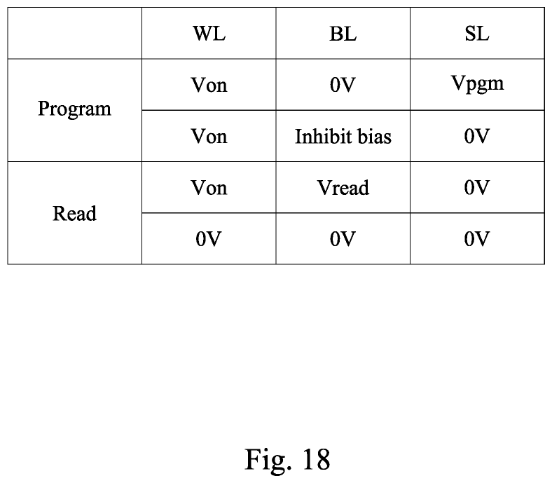

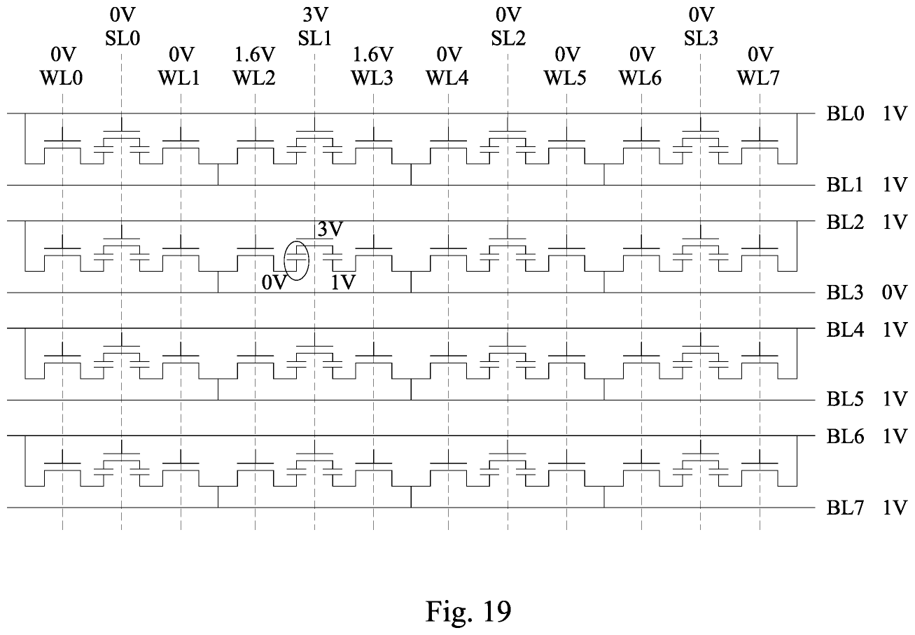

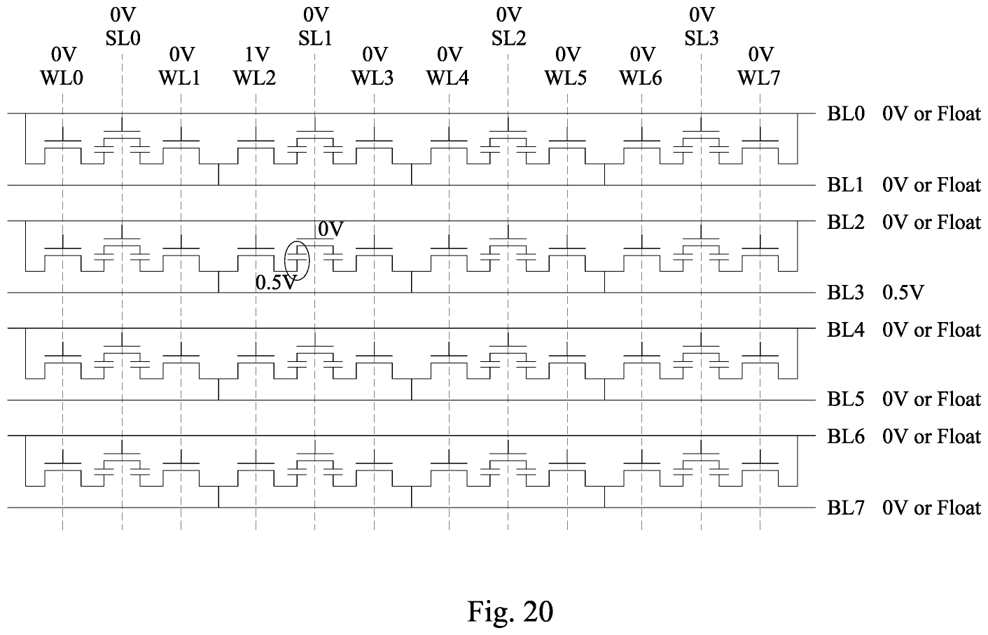

FIG. 17 is an equivalent circuit diagram of the layout the memory cells and the conductive lines in accordance with some embodiments. FIG. 18 is an operating table of FIG. 17. FIG. 19 is a voltage biased conditions assigned to word lines, bit line, source lines of the selected block and the remaining multiple unselected blocks within the memory array in a program (PGM) operation of the present disclosure. FIG. 20 is a voltage biased conditions assigned to word lines, bit line, source lines of the selected block and the remaining multiple unselected blocks within the memory array in a read operation of the present disclosure. Reference is made to FIGS. 17, 18 and 19. The memory cells in the layout are disposed between pairs of bit lines BL0-BL7. For example, the memory cells in a first column are disposed between the bit lines BL0 and BL1. The memory cells in a second column are between the bit line BL2 and BL3. The memory cells in a third column are between the bit lines BL4 and BL5. The memory cells in a fourth column are between the bit lines BL6 and BL7.

In the program operation, 0V is applied to a selected bit line (BL), an inhibit bias voltage is applied to un-selected bit lines (BLs) to inhibit discharging of the corresponding global bit lines (BLs). In this embodiment, 0V is applied to the selected bit line BL3. The inhibit voltage equals to 1 V and is applied to un-selected bit lines BL0-BL2 and BL4-BL7.

A program voltage (Vpgm) is applied to a selected source line. 0V is applied to un-selected source lines (SLs). In this embodiment, the program voltage (Vpgm) equals to 3V and is applied to the source line SL1. 0 V is applied to un-selected sources lines SL0, SL2 and SL3. The gate of the transistor connected to the selected source line SL1 has a voltage level of 3V. A turn on voltage (Von) is applied to a selected word line (WL) and a non-selected word line (WL). In this embodiment, the turn on voltage (Von) equals to 1.6V and is applied to the selected word line WL2 and the un-selected word line WL3. 0V are applied to the other word lines WL0, WL1, WL4, WL5, WL6 and WL7. The source of the transistor connected to the bit line BL2 and has a voltage level of 1V. The drain of the transistor connected to the bit line BL3 and has a voltage level of 0V. A fuse in the bit line BL3 is thus formed using a circle symbol shown in FIG. 19.

In the read operation, a read voltage (Vread) is applied to a selected bit line (BL), 0V is applied to un-selected bit lines (BLs). In this embodiment, read voltage (Vread) equals to 0.5V and is applied to the selected bit line BL3. 0V is applied to un-selected bit lines BL0-BL2 and BL4-BL7. In some embodiments, the un-selected bit lines BL0-BL2 and BL4-BL7 are floated.

0V is applied to a selected source line. 0V is applied to un-selected source lines (SLs). In this embodiment, 0V is applied to the selected source line SL1. 0 V is applied to un-selected sources lines SL0, SL2 and SL3. The gate of the transistor connected to the selected source line SL1 has a voltage level of 0V. A turn on voltage (Von) is applied to a selected word line. 0V is applied to a un-selected word line. In this embodiment, the turn on voltage (Von) equals to 1V and is applied to the selected word line WL2. 0V is applied to un-selected word lines WL0, WL1, WL3-WL7. The drain of the transistor connected to the bit line BL3 and has a voltage level of 0.5V. Current may flow from the drain of the transistor to the gate of the transistor.

Based on the above discussions, it can be seen that the present disclosure offers advantages. It is understood, however, that other embodiments may offer additional advantages, and not all advantageous are necessarily disclosed herein, and that no particular advantage is required for all embodiments. One advantage is that the memory cell has a small cell area such that it can be used for all technology nodes. Another advantage is that the source line oxide can provide isolation between adjacent memory cells and thus suppress the leakage therebetween. Yet another advantage is that the logic poly gate has bottom tip portions which can provide point discharge structure. The point discharge structure can greatly enhance an oxide breakdown due to providing the high electric filed.

In some embodiments, an anti-fuse memory cell includes a substrate, a gate dielectric layer over the substrate, a word line gate over the gate dielectric layer, a first implant region on a first side of the word line gate, a bit line contact plug over the first implant region, a second implant region on a second side of the word line gate opposite the first side of the word line gate, an oxidized region on the second implant region and having a convex upper surface and a source line gate over the convex upper surface of the oxidized region. The oxidized region has an oval shape when viewed from cross section. The second implant region has a concave upper surface. The oxidized region has a convex lower surface. The anti-fuse memory cell further includes a third implant region under the word line gate. The anti-fuse memory cell further includes an oxide spacer wrapping around a top and opposite sidewalls of the word line gate. The oxidized region has a maximum thickness greater than a thickness of the gate dielectric layer. The source line gate has a top surface higher than a top surface of the word line gate.

In some embodiments, an anti-fuse memory cell includes a substrate, a first gate dielectric layer over the substrate, a first word line gate over the first gate dielectric layer, a first implant region on a first side of the first word line gate, a first bit line contact plug over the first implant region, a second implant region on a second side of the first word line gate opposite the first side of the first word line gate, an oxidized region on the second implant region and a source line gate over the oxidized region. The source line gate has a center thickness different from an edge thickness of the source line gate. The center thickness of the source line gate is less than the edge thickness of the source line gate. The oxidized region has a topmost position higher than a top surface of the gate dielectric layer. The source line gate and the oxidized region form an interface having a curved profile. The anti-fuse memory cell further includes a second gate dielectric layer, a second word line gate, a third implant region and a second bit line contact plug. The second gate dielectric layer is over the substrate. The second word line gate is over the second gate dielectric layer. The first and the second word line gates are on opposite sides of the source line gate, respectively. The third implant region is on a side of the second word line gate away from the source line gate. The second bit line contact plug is over the third implant region. The anti-fuse memory cell further includes a fourth implant region under the second word line gate. The source line gate has a top surface higher than top surfaces of both the first and second word line gates. The third implant region is of a conductivity type opposite a conductivity type of the second implant region.

In some embodiments, a method of forming an anti-fuse memory cell includes forming a gate dielectric layer over a substrate, forming a first word line gate and a second word line gate over the gate dielectric layer, performing a first ion implantation process to form a first implant region of a first conductivity type in the substrate and laterally between the first and second word line gates, performing an oxidation process to the first implant region to form an oxidized region raised above a top surface of the substrate, forming a source line gate over the oxidized region, performing a second ion implantation process to form second implant regions of a second conductivity type in the substrate, with the first and second word line gates laterally between the second implant region, and forming bit line contact plugs over the second implant regions, respectively. In some embodiments, forming the source line gate includes depositing a gate material over the oxidized region and planarizing the gate material. In some embodiments, the method further includes prior to forming the first implant region, forming a spacer layer over the first and second word line gates and the gate dielectric layer, and after forming the first implant region, etching the spacer layer to form a first spacer wrapping around three sides of the first word line gate and a second spacer wrapping around three sides of the second word line gate. In some embodiments, the method further includes after forming the first and second spacers, depositing an oxide layer conformally over the first and second spacers and the first implant region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An anti-fuse memory cell, comprising:
a substrate;
a gate dielectric layer over the substrate;
a word line gate over the gate dielectric layer;
a first implant region on a first side of the word line gate;
a bit line contact plug over the first implant region;
a second implant region on a second side of the word line gate opposite the first side of the word line gate;
an oxidized region on the second implant region and having a convex upper surface; and
a source line gate over the convex upper surface of the oxidized region.

2. The anti-fuse memory cell of claim 1, wherein the oxidized region has an oval shape when viewed from cross section.

3. The anti-fuse memory cell of claim 1, wherein the second implant region has a concave upper surface.

4. The anti-fuse memory cell of claim 1, wherein the oxidized region has a convex lower surface.

5. The anti-fuse memory cell of claim 1, further comprising:
a third implant region under the word line gate.

6. The anti-fuse memory cell of claim 1, further comprising:
an oxide spacer wrapping around a top and opposite sidewalls of the word line gate.

7. The anti-fuse memory cell of claim 1, wherein the oxidized region has a maximum thickness greater than a thickness of the gate dielectric layer.

8. The anti-fuse memory cell of claim 1, wherein the source line gate has a top surface higher than a top surface of the word line gate.

9. An anti-fuse memory cell, comprising:
a substrate;
a first gate dielectric layer over the substrate;
a first word line gate over the first gate dielectric layer;
a first implant region on a first side of the first word line gate;
a first bit line contact plug over the first implant region;
a second implant region on a second side of the first word line gate opposite the first side of the first word line gate;
an oxidized region on the second implant region; and
a source line gate over the oxidized region, wherein the source line gate has a center thickness different from an edge thickness of the source line gate.

10. The anti-fuse memory cell of claim 9, wherein the center thickness of the source line gate is less than the edge thickness of the source line gate.

11. The anti-fuse memory cell of claim 9, wherein the oxidized region has a topmost position higher than a top surface of the gate dielectric layer.

12. The anti-fuse memory cell of claim 9, wherein the source line gate and the oxidized region form an interface having a curved profile.

13. The anti-fuse memory cell of claim 9, further comprising:
a second gate dielectric layer over the substrate;
a second word line gate over the second gate dielectric layer, wherein the first and the second word line gates are on opposite sides of the source line gate, respectively;
a third implant region on a side of the second word line gate away from the source line gate; and
a second bit line contact plug over the third implant region.

14. The anti-fuse memory cell of claim 13, further comprising:
a fourth implant region under the second word line gate.

15. The anti-fuse memory cell of claim 13, wherein the source line gate has a top surface higher than top surfaces of both the first and second word line gates.

16. The anti-fuse memory cell of claim 13, wherein the third implant region is of a conductivity type opposite a conductivity type of the second implant region.

17. A method of forming an anti-fuse memory cell, comprising:
forming a gate dielectric layer over a substrate;
forming a first word line gate and a second word line gate over the gate dielectric layer;
performing a first ion implantation process to form a first implant region of a first conductivity type in the substrate and laterally between the first and second word line gates;
performing an oxidation process to the first implant region to form an oxidized region raised above a top surface of the substrate;
forming a source line gate over the oxidized region;
performing a second ion implantation process to form second implant regions of a second conductivity type in the substrate, with the first and second word line gates laterally between the second implant region; and
forming bit line contact plugs over the second implant regions, respectively.

18. The method of claim 17, wherein forming the source line gate comprises:
depositing a gate material over the oxidized region; and
planarizing the gate material.

19. The method of claim 17, further comprising:
prior to forming the first implant region, forming a spacer layer over the first and second word line gates and the gate dielectric layer; and
after forming the first implant region, etching the spacer layer to form a first spacer wrapping around three sides of the first word line gate and a second spacer wrapping around three sides of the second word line gate.

20. The method of claim 19, further comprising:
after forming the first and second spacers, depositing an oxide layer conformally over the first and second spacers and the first implant region.
